(19) United States
(12) Patent Application Publication
(10) Pub. No.: US 2025/0338679 A1
(43) Pub. Date: Oct. 30, 2025

(54) DISPLAY PANEL AND MANUFACTURING METHOD THEREOF

(71) Applicant: AUO Corporation, Hsinchu (TW)

(72) Inventors: Shiuan-Tzung Cheng, Hsinchu (TW); Cheng-Liang Wang, Hsinchu (TW)

(73) Assignee: AUO Corporation, Hsinchu (TW)

(21) Appl. No.: 18/792,588

(22) Filed: Aug. 2, 2024

(30) Foreign Application Priority Data
Apr. 30, 2024 (TW) 113116086

(51) Int. Cl. H01L 33/50; H01L 25/075; H01L 33/54; H01L 33/62

(52) U.S. Cl. CPC H10H 20/8514; H01L 25/0753; H10H 20/853; H10H 20/857; H10H 20/0361; H10H 20/0364

(57) ABSTRACT

A display panel including a circuit substrate, a first light-emitting element, a first color conversion layer, a first color filter layer, a second light-emitting element, and an encapsulation layer is provided. The first light-emitting element is configured to emit blue light and/or ultraviolet light. The first color conversion layer covers the first light-emitting element and is configured to convert blue light and/or ultraviolet light into red light. The first color filter layer covers and contacts a top surface of the first color conversion layer. The second light-emitting element is configured to emit blue light. The encapsulation layer surrounds the first light-emitting element, the first color conversion layer, the first color filter layer, and the second light-emitting element.

### CROSS-REFERENCE TO RELATED APPLICATION

This application claims the priority benefit of Taiwan application serial no. 113116086, filed on Apr. 30, 2024. The entirety of the above-mentioned patent application is hereby incorporated by reference herein and made a part of this specification.

### BACKGROUND

### Technical Field

The disclosure relates to a display panel and a manufacturing method thereof.

### Description of Related Art

Along with advancement of science and technology, resolution of display devices is gradually improved. In a high-resolution display device, a distance between adjacent sub-pixels is very small, causing sub-pixels of different colors to easily interfere with each other, thereby affecting quality of a display image. In a micro-LED display panel, each sub-pixel contains a micro-LED. Generally, a bank structure is provided between two adjacent micro-LEDs, and this bank structure may be used to block light to prevent different sub-pixels from interfering with each other. However, along with the improvement of resolution, the distance between the micro-LEDs is too small, making it difficult to produce a bank structure that meets the needs. In addition, in some flexible or stretchable display panels, after the panel is deformed, the light emitted by the micro-LEDs may probably pass through gaps around the bank structure, causing problems of shot mura or color shift in images.

### SUMMARY

The disclosure is directed to a display panel, which mitigates problems of shot mura or color shift in images.

At least one embodiment of the disclosure provides a display panel including a circuit substrate, a first light-emitting element, a first color conversion layer, a first color filter layer, a second light-emitting element, and an encapsulation layer. The first light-emitting element is electrically connected to the circuit substrate, and is configured to emit blue light and/or ultraviolet light. The first color conversion layer covers the first light-emitting element and is configured to convert blue light and/or ultraviolet light into red light. The first color filter layer covers and contacts a top surface of the first color conversion layer, and is configured to have a transmittance of 0% to 5% for blue light and/or ultraviolet light. The first color filter layer is configured to have a transmittance of 60% to 99% for red light. The second light-emitting element is electrically connected to the circuit substrate, and is configured to emit blue light. The first color conversion layer and the first color filter layer are separated from the second light-emitting element. The encapsulation layer surrounds the first light-emitting element, the first color conversion layer, the first color filter layer, and the second light-emitting element.

At least one embodiment of the disclosure provides a display panel including a circuit substrate, a first light-emitting element, a first color conversion layer, a first color filter layer, a second light-emitting element, and an encapsulation layer. The first light-emitting element is electrically connected to the circuit substrate, and is configured to emit blue light and/or ultraviolet light. The first color conversion layer covers the first light-emitting element and is configured to convert blue light and/or ultraviolet light into red light. The first color filter layer completely covers and the first color conversion layer, and is configured to have a transmittance of 0% to 5% for blue light and/or ultraviolet light. The first color filter layer is configured to have a transmittance of 60% to 99% for red light. The second light-emitting element is electrically connected to the circuit substrate, and is configured to emit blue light. The first color conversion layer and the first color filter layer are separated from the second light-emitting element. The encapsulation layer surrounds the first light-emitting element, the first color conversion layer, the first color filter layer, and the second light-emitting element.

At least one embodiment of the disclosure provides a manufacturing method of a display panel, which includes following steps. A first light-emitting element and a second light-emitting element are electrically connected to a circuit substrate, wherein the first light-emitting element is configured to emit blue light and/or ultraviolet light, and the second light-emitting element is configured to emit blue light. A first color conversion layer is formed to cover the first light-emitting element, and the first color conversion layer is separated from the second light-emitting element. The first color conversion layer is configured to convert blue light and/or ultraviolet light into red light. A first color filter layer is formed on the first color conversion layer, and the first color filter layer is separated from the second light-emitting element. The first color filter layer is configured to have a transmittance of 0% to 5% for blue light and/or ultraviolet light, and the first color filter layer is configured to have a transmittance of 60% to 99% for red light.

### BRIEF DESCRIPTION OF THE DRAWINGS

FIG. 1A to FIG. 1D are schematic top views of a manufacturing method of a display panel according to an embodiment of the disclosure.

FIG. 2A to FIG. 2E are schematic cross-sectional views of the manufacturing method of the display panel according to an embodiment of the disclosure.

FIG. 3A to FIG. 3D are schematic top views of a manufacturing method of a display panel according to another embodiment of the disclosure.

FIG. 4A to FIG. 4E are schematic cross-sectional views of the manufacturing method of the display panel according to another embodiment of the disclosure.

### DESCRIPTION OF THE EMBODIMENTS

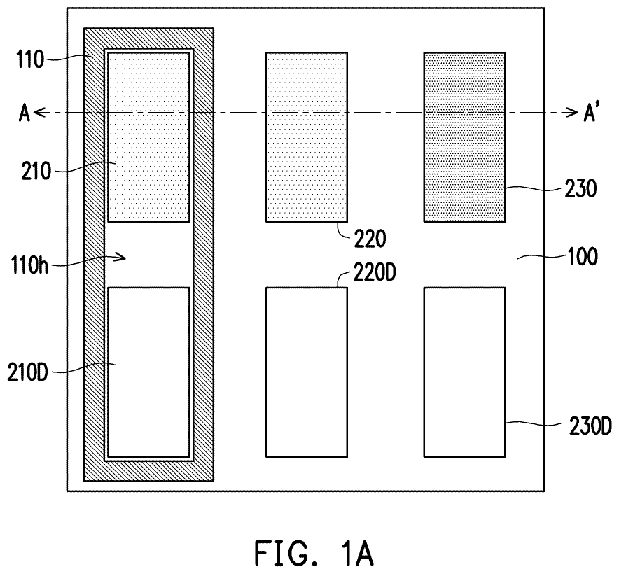

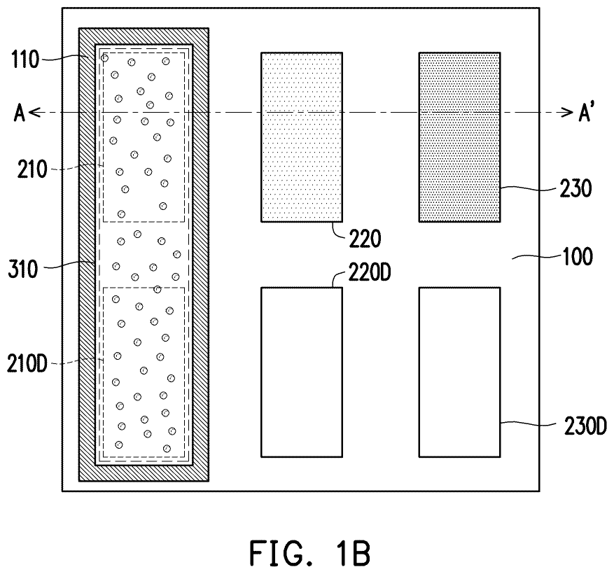

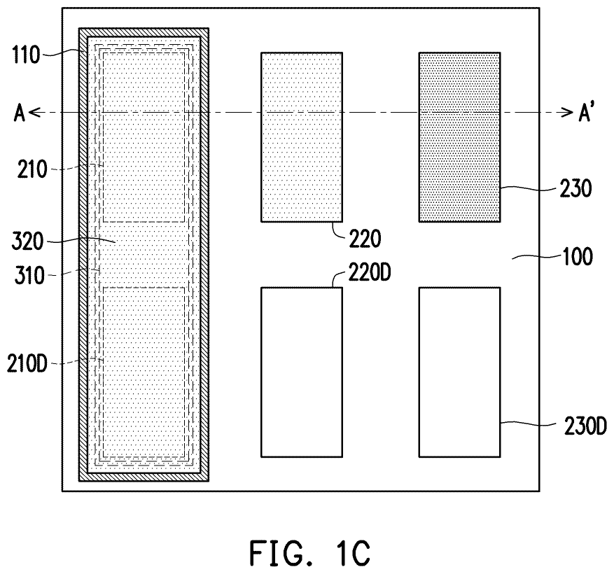

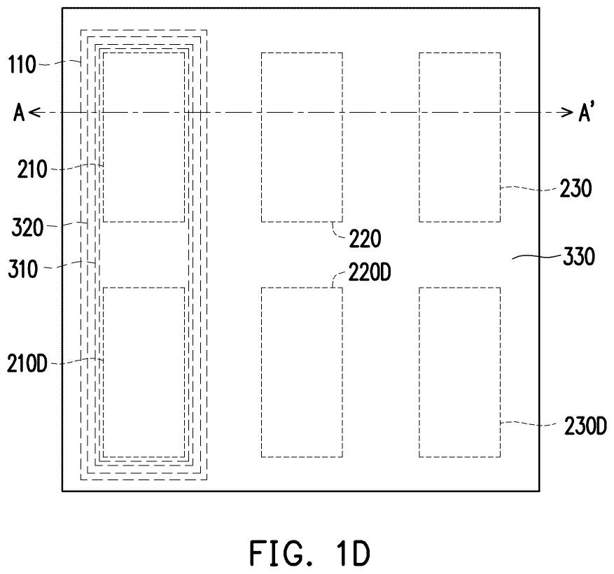

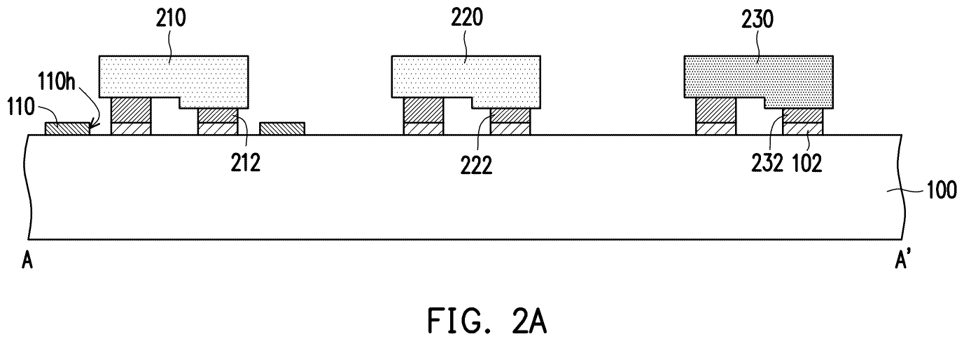

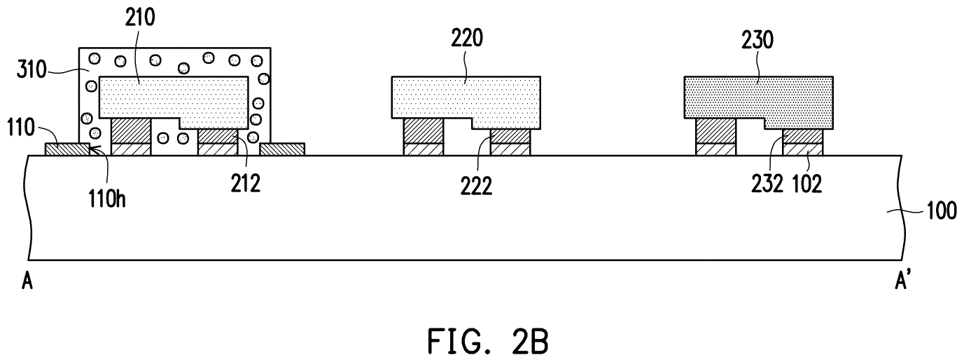

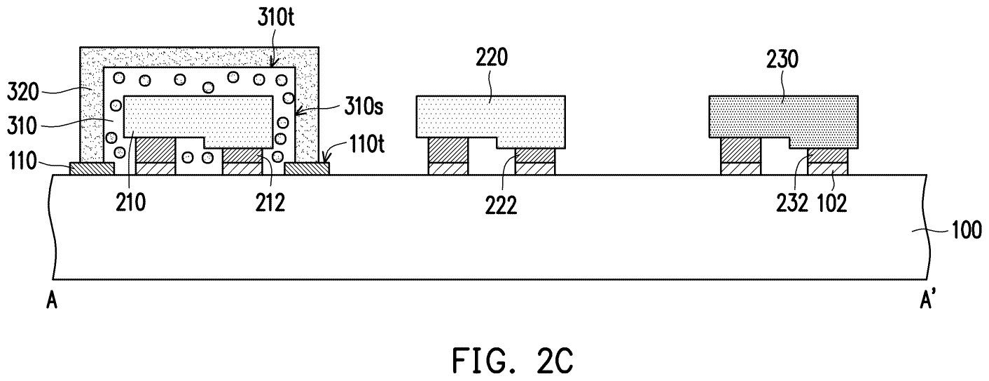

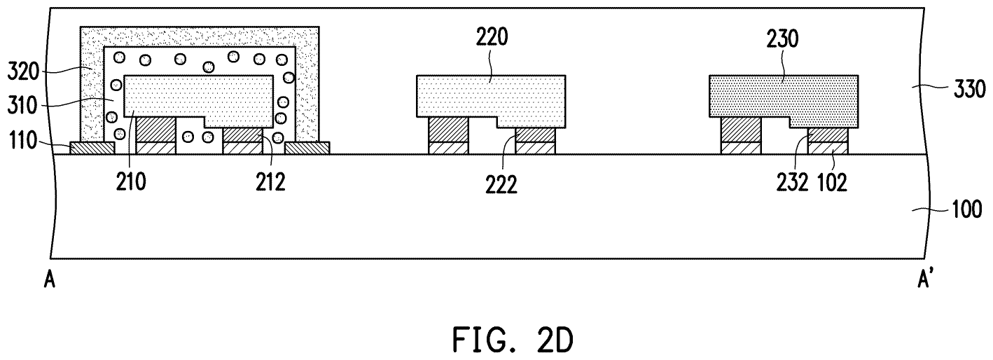

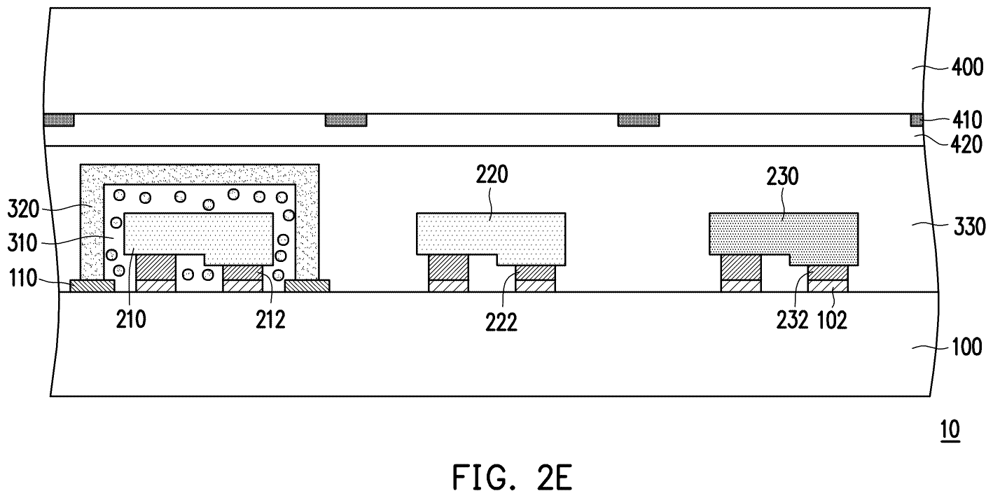

FIG. 1A to FIG. 1D are schematic top views of a manufacturing method of a display panel 10 according to an embodiment of the disclosure. FIG. 2A to FIG. 2E are schematic cross-sectional views of the manufacturing method of the display panel 10 according to an embodiment of the disclosure, where FIG. 2A to FIG. 2D respectively correspond to positions of line A-A′ in FIG. 1A to FIG. 1D. Referring to FIG. 1A and FIG. 1B, a circuit substrate 100 is provided. In some embodiments, the circuit substrate 100 includes a substrate and a circuit structure located thereon. The substrate is, for example, a rigid substrate, and a material thereof may be glass, quartz, organic polymers, or opaque/reflective materials (such as conductive materials, metals, wafers, ceramics, or other applicable materials) or are other applicable materials. However, the disclosure is not limited thereto. In other embodiments, the substrate may also be a flexible substrate or a stretchable substrate. In other words, the circuit substrate 100 may be a flexible circuit substrate or a stretchable circuit substrate. In some embodiments, a material of the flexible substrate and the stretchable substrate includes polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (polyurethane PU) or other suitable materials.

The circuit structure in the circuit substrate 100 includes, for example, multiple layers of conductive layers (not shown) and multiple layers of insulating layers (not shown). In some embodiments, the circuit structure includes a plurality of active components (not shown) and/or a plurality of passive components (not shown), and the active components (not shown) may be thin film transistors. In some embodiments, the circuit structure includes a plurality of bonding pads 102.

The first light-emitting element 210, the second light-emitting element 220, and the third light-emitting element 230 are electrically connected to the circuit substrate 100. In the embodiment, the first light-emitting element 210 is electrically connected to the corresponding bonding pad 102 through a first conductive structure 212; the second light-emitting element 220 is electrically connected to the corresponding bonding pad 102 through a second conductive structure 222; and the third light-emitting element 230 is electrically connected to the corresponding bonding pad 102 through a third conductive structure 232. The numbers of the first light-emitting element 210, the second light-emitting element 220, and the third light-emitting element 230 may be adjusted according to actual requirements.

The first light-emitting element 210, the second light-emitting element 220, and the third light-emitting element 230 are horizontal light-emitting diodes or vertical light-emitting diodes. In FIG. 2A, a horizontal light-emitting diode is taken as an example for explanation.

The first light-emitting element 210 is configured to emit blue light and/or ultraviolet light. The second light-emitting element 220 is configured to emit blue light. The third light-emitting element 230 is configured to emit green light. In some embodiments, the first light-emitting element 210 and the second light-emitting element 220 include the same light-emitting diodes (for example, both are blue light-emitting diodes). In some embodiments, the above-mentioned blue light means light with a wavelength between 380 nm and 500 nm, the above-mentioned ultraviolet light means light with a wavelength between 100 nm and 380 nm, and the above-mentioned green light means light with a wavelength between 501 nm and 570 nm.

In some embodiments, a barrier layer 110 is optionally formed on the circuit substrate 100. The barrier layer 110 has an opening 110h overlapping the first light-emitting element 210. Although in the embodiment, the barrier layer 110 is only formed around the first light-emitting element 210, the disclosure is not limited thereto. In other embodiments, the barrier layer 110 is also formed around the second light-emitting element 220 and the third light-emitting element 230. In other words, in other embodiments, in addition to surrounding the first light-emitting element 210, the barrier layer 110 may also surround the second light-emitting element 220 and the third light-emitting element 230.

In some embodiments, the barrier layer 110 includes a light-shielding material, which is adapted to reduce crosstalk between different sub-pixels. In some embodiments, a method of forming the barrier layer 110 includes: first forming a photoresist material on the circuit substrate 100, and then patterning the photoresist material through a photolithography process to form the barrier layer 110. In some embodiments, the aforementioned photoresist material includes a hydrophobic material.

In the embodiment, the circuit substrate 100 includes a first repair area 210D, a second repair area 220D, and a third repair area 230D. During a repair process, light-emitting diodes for repair may be disposed in the first repair area 210D, the second repair area 220D, and the third repair area 230D. For example, if the first light-emitting element 210 fails or the first light-emitting element 210 is not correctly bonded to the bonding pad 102, a light-emitting diode for repair is disposed in the first repair area 210D. In some embodiments, bonding pads for repair (not shown) are disposed in the first repair area 210D, the second repair area 220D, and the third repair area 230D, and the light-emitting diodes for repair are bonded to the aforementioned bonding pads.

Referring to FIG. 1B and FIG. 2B, a first color conversion layer 310 is formed to cover the first light-emitting element 210. The first color conversion layer 310 is separated from the second light-emitting element 220 and the third light-emitting element 230.

In some embodiments, the first color conversion layer 310 is formed through a photolithography process. For example, a photoresist material layer is first formed on the circuit substrate 100, where the photoresist material layer covers the first light-emitting element 210, the second light-emitting element 220, and the third light-emitting element 230. Then, the photoresist material layer is patterned through a photolithography process to form the first color conversion layer 310 and expose the second light-emitting element 220 and the third light-emitting element 230.

In other embodiments, the first color conversion layer 310 is formed by inkjet printing. The first color conversion layer 310 is located in the opening 110h of the barrier layer 110. In this case, the hydrophobic barrier layer 110 may be used to prevent uncured ink from flowing to unwanted places, which helps to prevent the first color conversion layer 310 from contacting the second light-emitting element 220 or the third light-emitting element 230.

In some embodiments, the first color conversion layer 310 is configured to convert blue light and/or ultraviolet light emitted by the first light-emitting element 210 into red light. In some embodiments, the above-mentioned red light means light with a wavelength between 600 nm and 750 nm. In some embodiments, the first color conversion layer 310 includes a polymer material (or organic material) and color conversion particles dispersed therein. The aforementioned color conversion particles include at least one of a quantum dot material, a fluorescent material, and a perovskite material. In some embodiments, the first color conversion layer 310 may also include a scattering material (such as TiO_{X}, etc.).

Referring to FIG. 1C and FIG. 2C, a first color filter layer 320 is formed on the first color conversion layer 310. The first color filter layer 320 covers and contacts a top surface 310t and a side surface 310s of the first color conversion layer 310. In some embodiments, in a top view, the first color filter layer 320 completely covers the first color conversion layer 310. In some embodiments, the first color filter layer 320 extends from the top surface 310t of the first color conversion layer 310 toward the circuit substrate 100 along the side surface 310s of the first color conversion layer 310. For example, the first color filter layer 320 extends to a top surface 110t of the barrier layer 110. The first color filter layer 320 is separated from the second light-emitting element 220 and the third light-emitting element 230.

In some embodiments, the first color filter layer 320 is formed through a photolithography process. For example, a photoresist material layer is first formed on the circuit substrate 100, the first color conversion layer 310, the second light-emitting element 220, and the third light-emitting element 230, where the photoresist material layer covers the first color conversion layer 310, the second light-emitting element 220, and the third light-emitting element 230. Then, the photoresist material layer is patterned through a photolithography process to form the first color filter layer 320 and expose the second light-emitting element 220 and the third light-emitting element 230.

The first color filter layer 320 is configured to have a transmittance of 0% to 5% for blue light and/or ultraviolet light, and a transmittance of 60% to 99% for red light. Therefore, the first color filter layer 320 may prevent blue light and/or ultraviolet light emitted by the first light-emitting element 210 from directly passing through, and may allow red light emitted by the first color conversion layer 310 to pass through.

In addition, blue light emitted by the second light-emitting element 220 adjacent to the first light-emitting element 210 may also be filtered by the first color filter layer 320, thereby preventing the first color conversion layer 310 from being excited by the second light-emitting element 220. Based on the above, the problem of mutual interference between blue sub-pixels and red sub-pixels may be mitigated.

In addition, in the embodiment, through the arrangement of the first color conversion layer 310, the mutual interference between two sub-pixels may be mitigated without configuring a bank structure between the first light-emitting element 210 and the second light-emitting element 220. Therefore, problems of shot mura or color shift in images caused by deformation of the bank structure may be avoided.

Referring to FIG. 1D and FIG. 2D, after forming the first color filter layer 320, an encapsulation layer 330 is formed on the circuit substrate 100. The encapsulation layer 330 surrounds the first light-emitting element 210, the first color conversion layer 310, the first color filter layer 320, the second light-emitting element 220, and the third light-emitting element 230. In some embodiments, the encapsulation layer 330 contacts the second light-emitting element 220 and the third light-emitting element 230, and the encapsulation layer 330 is separated from the first light-emitting element 210 and the first color conversion layer 310. In some embodiments, the encapsulation layer 330 contacts the first color filter layer 320.

In the embodiment, the encapsulation layer 330 includes a transparent material, and red light, blue light, and the green light may all penetrate through the encapsulation layer 330.

Finally, referring to FIG. 2E, an opposite substrate 400 is optionally bonded to the encapsulation layer 330. In some embodiments, the opposite substrate 400 is connected to the encapsulation layer 330 through an adhesive layer 420. In some embodiments, a black matrix 410 is formed on the opposite substrate 400.

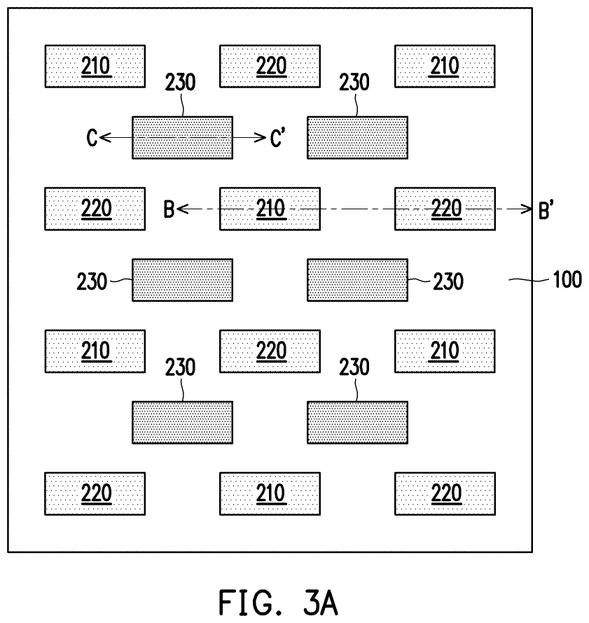

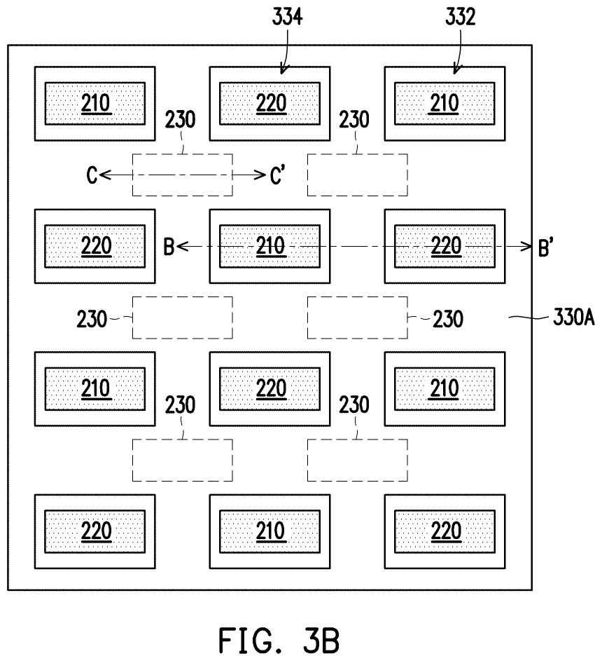

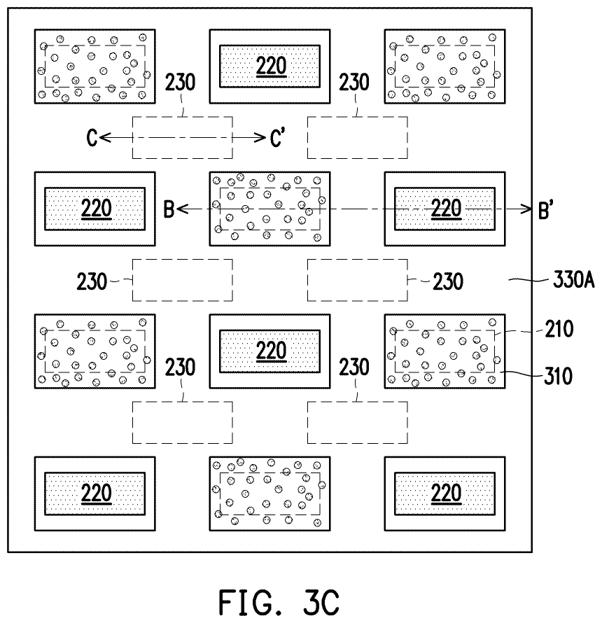

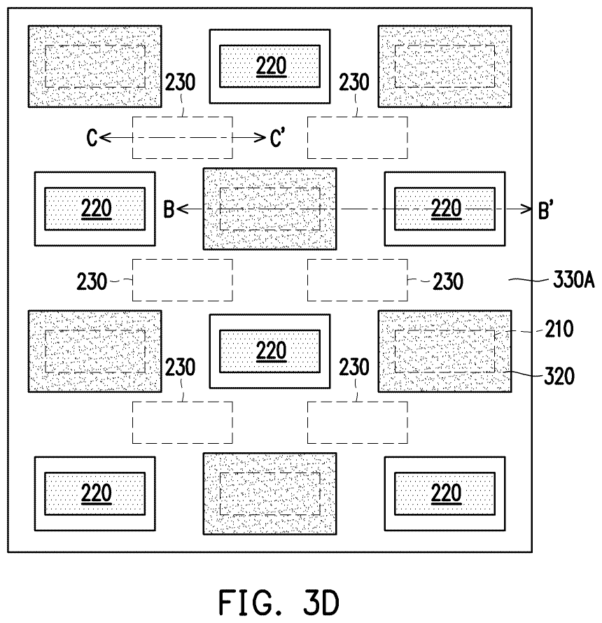

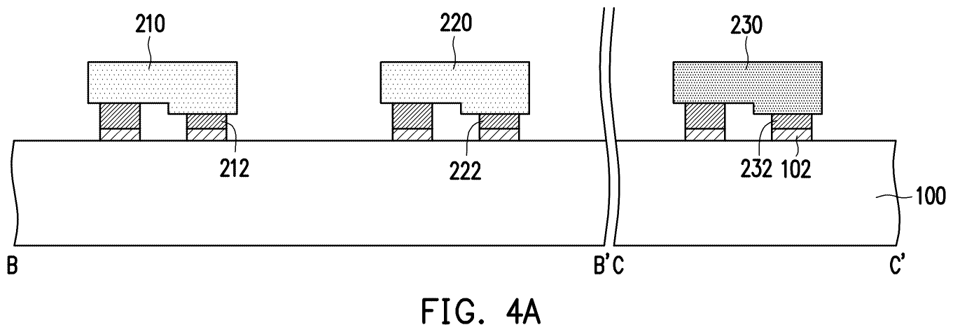

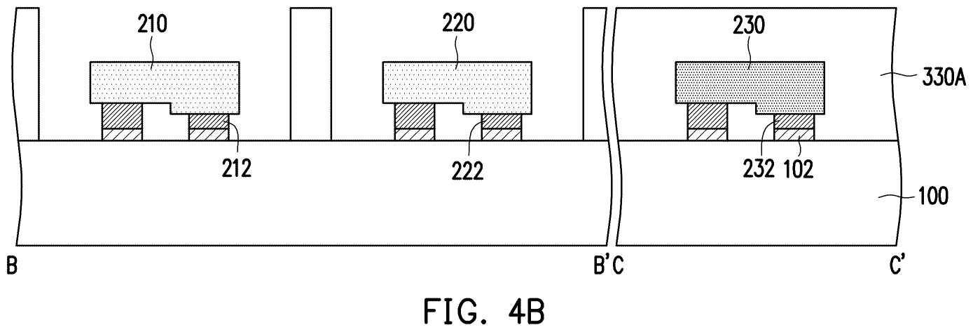

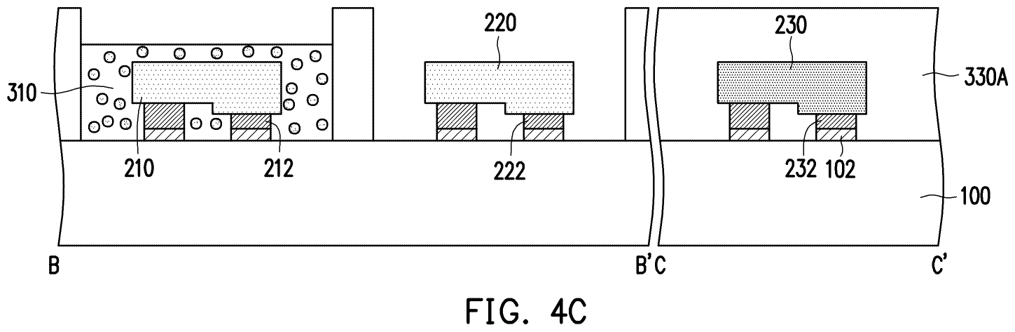

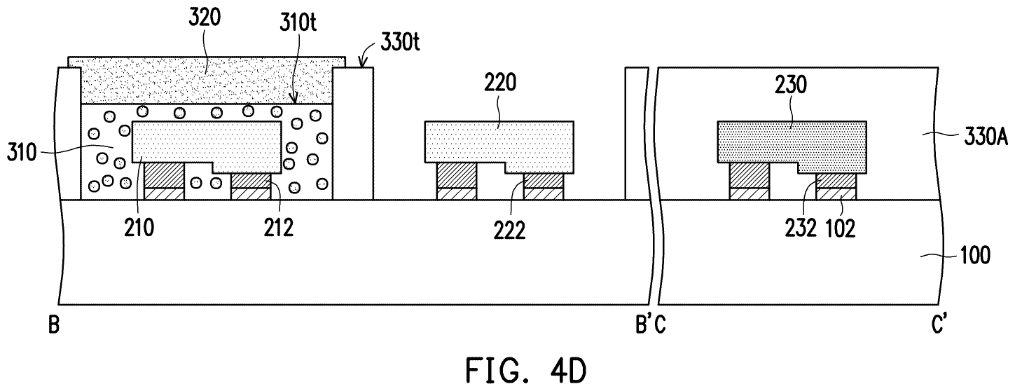

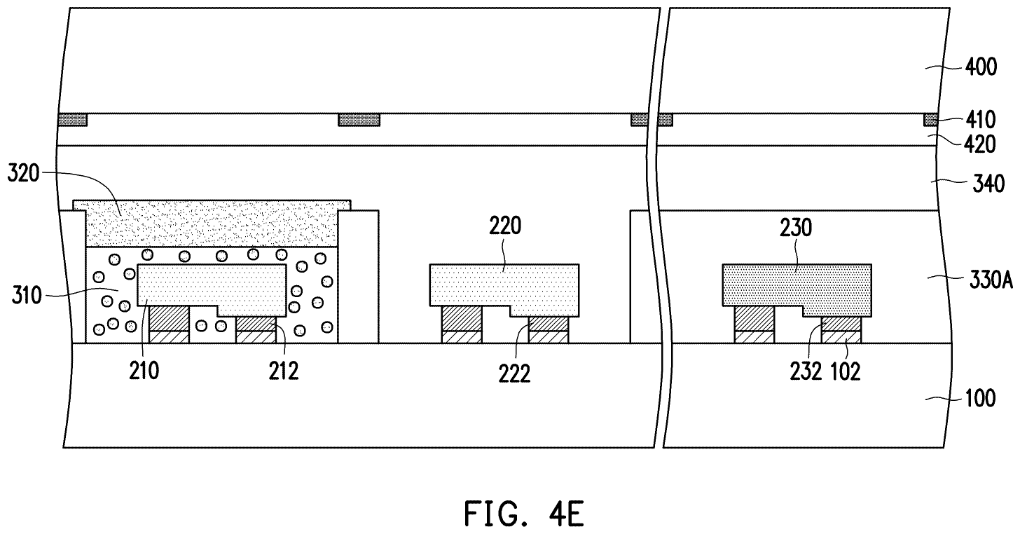

FIG. 3A to FIG. 3D are schematic top views of a manufacturing method of a display panel 20 according to another embodiment of the disclosure. FIG. 4A to FIG. 4E are schematic cross-sectional views of the manufacturing method of the display panel according to another embodiment of the disclosure, where FIG. 4A to FIG. 4D respectively correspond to positions of lines B-B′ and C-C′ in FIG. 3A to FIG. 3D. It should be noted here that the embodiment of FIG. 3A to FIG. 4E use the component numbers and a part of the content of the embodiment of FIG. 1A to FIG. 2E, where the same or similar numbers are used to represent the same or similar elements, and descriptions of the same technical content are omitted. For descriptions of the omitted parts, reference may be made to the foregoing embodiments, which will not be repeated.

Referring to FIG. 3A and FIG. 4A, a plurality of first light-emitting elements 210, a plurality of second light-emitting elements 220, and a plurality of third light-emitting elements 230 are electrically connected to the circuit substrate 100. In the embodiment, the first light-emitting elements 210 are respectively electrically connected to the corresponding bonding pads 102 through the first conductive structures 212; the second light-emitting elements 220 are respectively electrically connected to the corresponding bonding pads 102 through the second conductive structures 222; and the third light-emitting elements 230 are respectively electrically connected to the corresponding bonding pads 102 through the third conductive structures 232.

In some embodiments, at least one of the first light-emitting elements 210 is surrounded by four of the third light-emitting elements 230, and at least one of the second light-emitting elements 220 is surrounded by four of the third light-emitting elements 230.

Referring to FIG. 3B and FIG. 4B, an encapsulation layer 330A is formed on the circuit substrate 100. The encapsulation layer 330A surrounds the first light-emitting elements 210, the second light-emitting elements 220, and the third light-emitting elements 230.

In some embodiments, the encapsulation layer 330A is formed through a photolithography process. For example, a photoresist material layer is first formed on the circuit substrate 100, where the photoresist material layer covers the first light-emitting elements 210, the second light-emitting elements 220, and the third light-emitting elements 230. Then, the photoresist material layer is patterned through a photolithography process to form the encapsulation layer 330A, and expose the first light-emitting elements 210 and the second light-emitting elements 220. The encapsulation layer 330A has a plurality of first grooves 332 respectively overlapping the plurality of first light-emitting elements 210 and a plurality of second grooves 334 respectively overlapping the plurality of second light-emitting elements 220.

In some embodiments, the encapsulation layer 330A surrounds and contacts the third light-emitting elements 230, and the encapsulation layer 330A is configured to have a transmittance of 0% to 5% for blue light, and a transmittance of 60% to 99% for green light. In the embodiment, the encapsulation layer 330A may also be referred to as a green filter element, even if the encapsulation layer 330A covers a top surface of the third light-emitting element 230, green light emitted by the third light-emitting element 230 may pass through the encapsulation layer 330A. On the other hand, blue light emitted by the first light-emitting element 210 is difficult to pass through the encapsulation layer 330A.

Referring to FIG. 3C and FIG. 4C, a plurality of first color conversion layers 310 are respectively formed in the plurality of first grooves 332. Each first color conversion layer 310 does not fill the corresponding first groove 332. The plurality of first color conversion layers 310 respectively cover the plurality of first light-emitting elements 210 and are configured to convert blue light and/or ultraviolet light emitted by the first light-emitting elements 210 into red light. The first color conversion layers 310 are separated from the second light-emitting elements 220 and the third light-emitting elements 230. The encapsulation layer 330A contacts sidewalls of the first color conversion layers 310.

In some embodiments, the first color conversion layers 310 are formed through a photolithography process. For example, a photoresist material layer is first formed on the circuit substrate 100, where the photoresist material layer covers the first light-emitting elements 210, the second light-emitting elements 220, and the encapsulation layer 330A. Then, the photoresist material layer is patterned through a photolithography process to leave the first color conversion layers 310 located in the first grooves 332 and expose the second light-emitting elements 220.

In other embodiments, the first color conversion layers 310 are formed in the first grooves 332 by inkjet printing.

In the embodiment, blue light emitted by the second light-emitting element 220 adjacent to the first light-emitting element 210 may be filtered by the encapsulation layer 330A, thereby preventing the first color conversion layer 310 from being excited by the second light-emitting element 220. Based on the above, the problem of mutual interference between blue sub-pixels and red sub-pixels may be mitigated. Therefore, through the arrangement of the encapsulation layer 330A, the mutual interference between two sub-pixels may be mitigated without configuring a bank structure between the first light-emitting element 210 and the second light-emitting element 220. Therefore, problems of shot mura or color shift in images caused by deformation of the bank structure may be avoided.

Referring to FIG. 3D and FIG. 4D, a plurality of first color filter layers 320 are respectively formed in the portions of the plurality of first grooves 332 that are not filled by the first color conversion layers 310. The plurality of first color filter layers 320 respectively cover and contact the top surfaces 310t of the plurality of first color conversion layers 310. In some embodiments, the first color filter layers 320 fill the first grooves 332 and contact a part of a top surface 330t of the encapsulation layer 330A, but the disclosure is not limited thereto. In other embodiments, a top surface of the first color filter layer 320 is lower than the top surface of the encapsulation layer 330A. The first color filter layers 320 are separated from the second light-emitting elements 220 and the third light-emitting elements 230. The encapsulation layer 330A contacts sidewalls of the first color filter layers 320. In some embodiments, the first color conversion layers 310 are completely covered by the encapsulation layer 330A and the first color filter layers 320.

In some embodiments, the first color filter layer 320 is formed through a photolithography process. For example, a photoresist material layer is first formed on the first color conversion layers 310, the second light-emitting elements 220, and the encapsulation layer 330A. Then, the photoresist material layer is patterned through a photolithography process to form the first color filter layers 320 and expose the second light-emitting elements 220.

In the embodiment, the first color filter layers 320 may prevent blue light and/or ultraviolet light emitted by the first light-emitting elements 210 from directly passing through, and may allow red light emitted by the first color conversion layers 310 to pass through.

Referring to FIG. 4E, after the first color filter layers 320 are formed, a cover layer 340 is optionally formed on the encapsulation layer 330A and the first color filter layers 320. In the embodiment, the cover layer 340 includes a transparent material, and red light, blue light, and green light may all pass through the cover layer 340.

Optionally, the opposite substrate 400 is bonded to the cover layer 340. In some embodiments, the opposite substrate 400 is connected to the cover layer 340 through an adhesive layer 420. In some embodiments, the black matrix 410 is formed on the opposite substrate 400.

In summary, in some embodiments of the disclosure, through the design of the first color filter layer and/or the encapsulation layer, the problem of mutual interference between adjacent sub-pixels may be mitigated, and the bank structure may be omitted to avoid the problems of shot mura or color shift in images caused by deformation of the bank structure.

What is claimed is:

1. A display panel, comprising:
a circuit substrate;
a first light-emitting element, electrically connected to the circuit substrate, and configured to emit blue light and/or ultraviolet light;
a first color conversion layer, covering the first light-emitting element, and configured to convert blue light and/or ultraviolet light into red light;
a first color filter layer, covering and contacting a top surface of the first color conversion layer, configured to have a transmittance of 0% to 5% for blue light and/or ultraviolet light, and configured to have a transmittance of 60% to 99% for red light;
a second light-emitting element, electrically connected to the circuit substrate, and configured to emit blue light, wherein the first color conversion layer and the first color filter layer are separated from the second light-emitting element; and
an encapsulation layer, surrounding the first light-emitting element, the first color conversion layer, the first color filter layer, and the second light-emitting element.

2. The display panel as claimed in claim 1, wherein the first color filter layer extends from the top surface of the first color conversion layer to the circuit substrate along a side surface of the first color conversion layer.

3. The display panel as claimed in claim 1, further comprising:
a barrier layer, located on the circuit substrate, and having an opening overlapping the first light-emitting element, wherein the first color conversion layer is located in the opening, and the first color filter layer extends from the top surface of the first color conversion layer to a top surface of the barrier layer along a side surface of the first color conversion layer.

4. The display panel as claimed in claim 1, further comprising:
a third light-emitting element, electrically connected to the circuit substrate, and configured to emit green light, wherein the encapsulation layer surrounds the third light-emitting element, and the encapsulation layer is configured to have a transmittance of 0% to 5% for red light, and have a transmittance of 60% to 99% for green light.

5. The display panel as claimed in claim 4, further comprising:
a plurality of first light-emitting elements, electrically connected to the circuit substrate, and configured to emit blue light and/or ultraviolet light;
a plurality of first color conversion layers, respectively covering the first light-emitting elements, and configured to convert blue light and/or ultraviolet light into red light;
a plurality of first color filter layers, respectively covering and contacting top surfaces of the first color conversion layers;
a plurality of second light-emitting elements, electrically connected to the circuit substrate, and configured to emit blue light, wherein the first color conversion layers and the first color filter layers are separated from the second light-emitting elements; and
a plurality of third light-emitting elements, electrically connected to the circuit substrate, and configured to emit green light, wherein at least one of the first light-emitting elements is surrounded by four of the third light-emitting elements, and at least one of the second light-emitting elements is surrounded by the other four of the third light-emitting elements.

6. The display panel as claimed in claim 1, wherein the encapsulation layer contacts the second light-emitting element, and the encapsulation layer is separated from the first light-emitting element.

7. A display panel, comprising:
a circuit substrate;
a first light-emitting element, electrically connected to the circuit substrate, and configured to emit blue light and/or ultraviolet light;
a first color conversion layer, covering the first light-emitting element, and configured to convert blue light and/or ultraviolet light into red light;
a first color filter layer, completely covering the first color conversion layer, configured to have a transmittance of 0% to 5% for blue light and/or ultraviolet light, and configured to have a transmittance of 60% to 99% for red light;
a second light-emitting element, electrically connected to the circuit substrate, and configured to emit blue light, wherein the first color conversion layer and the first color filter layer are separated from the second light-emitting element; and
an encapsulation layer, surrounding the first light-emitting element, the first color conversion layer, the first color filter layer, and the second light-emitting element.

8. A manufacturing method of a display panel, comprising:
electrically connecting a first light-emitting element and a second light-emitting element to a circuit substrate, wherein the first light-emitting element is configured to emit blue light and/or ultraviolet light, and the second light-emitting element is configured to emit blue light;
forming a first color conversion layer to cover the first light-emitting element, and separating the first color conversion layer from the second light-emitting element, wherein the first color conversion layer is configured to convert blue light and/or ultraviolet light into red light; and
forming a first color filter layer on the first color conversion layer, and separating the first color filter layer from the second light-emitting element, wherein the first color filter layer is configured to have a transmittance of 0% to 5% for blue light and/or ultraviolet light, and the first color filter layer is configured to have a transmittance of 60% to 99% for red light.

9. The manufacturing method of the display panel as claimed in claim 8, further comprising:
after forming the first color filter layer, forming an encapsulation layer to surround the first light-emitting element, the first color conversion layer, the first color filter layer, and the second light-emitting element.

10. The manufacturing method of the display panel as claimed in claim 8, further comprising:
electrically connecting a third light-emitting element to the circuit substrate, wherein the third light-emitting element is configured to emit green light;
before forming the first color conversion layer, forming an encapsulation layer surrounding the first light-emitting element, the second light-emitting element, and the third light-emitting element, wherein the encapsulation layer has a first groove overlapping the first light-emitting element and a second groove overlapping the second light-emitting element;
forming the first color conversion layer in the first groove, wherein the first color conversion layer does not fill the first groove; and
forming the first color filter layer in a portion of the first groove that is not filled by the first color conversion layer, wherein the encapsulation layer contacts a sidewall of the first color conversion layer and a sidewall of the first color filter layer.
